(19) United States
(12) Patent Application Publication
(10) Pub. No.: US 2025/0240904 A1
(43) Pub. Date: Jul. 24, 2025

(54) ELECTRONIC CONTROL DEVICE

(71) Applicant: HITACHI ASTEMO, LTD., Hitachinaka-shi, Ibaraki (JP)

(72) Inventors: Yasuhiro TSUYUKI, Tokyo (JP); Toshikazu SHIGYO, Hitachinaka-shi, Ibaraki (JP); Toshiaki ISHII, Tokyo (JP); Hiroshi HARUNA, Tokyo (JP)

(73) Assignee: HITACHI ASTEMO, LTD., Hitachinaka-shi, Ibaraki (JP)

(21) Appl. No.: 18/834,930

(22) PCT Filed: Feb. 16, 2023
(86) PCT No.: PCT/JP2023/005440

§ 371 Date: Jul. 31, 2024

(30) Foreign Application Priority Data
Apr. 28, 2022 (JP) 2022-074618

(51) Int. Cl. H05K 5/06; B60R 16/023; F16J 15/10; H05K 5/00

(52) U.S. Cl. CPC H05K 5/061; B60R 16/0239; F16J 15/104; H05K 5/0047

(57) ABSTRACT

An electronic control device includes a first chassis 20, a second chassis 30 fixed to face the first chassis 20, and a sealant 40 that seals an internal space formed by the first chassis 20 and the second chassis 30, in which the sealant 40 includes an OH group and a CH₃ group, and a surface treatment film 31a including the OH group and the CH₃ group is formed on at least a part of a surface region of at least one of the first chassis 20 and the second chassis 30, the surface region coming into contact with the sealant. This provides an electronic control device that can maintain an airtight structure without largely changing a structure of a sealant filled in a gap between a case and a cover even under a requirement against salt damage that is becoming stricter.

### TECHNICAL FIELD

The present invention relates to an electronic control device to be mounted in a vehicle.

### BACKGROUND ART

As an example of an in-vehicle control device capable of protecting a sealant even when the sealant is sandwiched by a fixing member for fixing to a vehicle while suppressing protrusion of the sealant toward an internal space side, the device described in PTL 1 includes a first chassis, a second chassis fixed to face the first chassis, and a sealant disposed between a rim of the first chassis and a rim of the second chassis to seal an internal space formed by the first chassis and the second chassis, where the first chassis is disposed further toward the internal space side than the sealant, faces the rim of the second chassis, and has a shape that suppresses movement of the sealant into the internal space side.

### CITATION LIST

### Patent Literature

PTL 1: WO 2017/038316 A1

### SUMMARY OF INVENTION

### Technical Problem

An electronic control device mounted in an engine room is required to have a high degree of freedom to be mounted so that the place for mounting will not be restricted. Typically, to be mounted and fixed to a vehicle, an electronic control device is provided with a flange or the like having a through hole, and is fixed by a bolt to a vehicle-side fixing member.

In recent years, as a method for simplifying work and reducing cost by not fixing with bolts, a method of fixing by sandwiching the electronic control device by a vehicle-side bracket or the like has become popular.

Also required are to satisfy a strict specification of environmental resistance regarding corrosion and deterioration and to have long life. In particular, a longer life against salt damage, for example, against salt water, is required, so that a sealing structure that avoids progress of crevice corrosion is important.

Due to increased functionality of electronic control devices, chassis have become large in size and the number of connector poles has been increased. Dispersed arrangement in an electronic control device and reduction in the number of terminal poles of connectors using wireless connection cannot be easily realized for an electronic control device for an engine mounted in an engine room and for an electronic control device for a transmission.

Also required for the chassis of the electronic control device are, though conflicting with the increase in size, lower height and lighter weight to contribute to improvement in fuel efficiency needed for cars. Thus, since a technique of forming a chassis maintaining small deformation and thin structure is needed, and not only aluminum electrolytic capacitors but also electronic components need to be made low height, a lower-height watertight sealing structure is needed as well as lower-height electronic components.

In particular, for chassis of engine electronic control devices mounted in an engine room, the thickness has become thinner and higher functionality requires heat dissipation properties, and there is a need of a chassis that is inexpensive, low-height, and lightweight, and has high heat dissipation properties. In many cases, such a chassis has a structure in which a hot-dip galvanized steel plate having excellent corrosion resistance or a lightweight aluminum die-casted part is used.

Conventionally, in a sealing structure of an electronic control device using such a metal chassis, a silicone-based sealant is applied to ensure airtightness with no need of special treatment on the chassis (see, for example, PTL 1).

In a conventional structure in PTL 1, a sealant is filled in a gap between a case and a cover to form an airtight structure with no special treatment on surfaces of the case and the cover.

Meanwhile, there being abnormal weather or the like these days, a demand for longer life against salt damage, for example, against salt water is increasingly rising. Specification for a salt damage resistance test have also getting stricter requiring, for example, a higher salt damage test temperature or immersion of test samples in salt water.

Under such circumstances, an airtight structure depending only on a sealant applied to a metal surface as in PTL 1 relies only on adhesion established by a hydrogen bond or a covalent bond between an OH group on the metal surface and an OH group of the sealant. However, it has become apparent that when the OH group on the metal surface is unstable, a requirement against salt damage that has become stricter cannot be satisfied, resulting in breakage of the hydrogen bond by water to cause a leakage defect. Thus, there is still a room for improvement.

An object of the present invention is to provide an electronic control device that can maintain an airtight structure without largely changing a structure of a sealant filled in a gap between a case and a cover even under a requirement against salt damage that is becoming stricter.

### Solution to Problem

The present invention includes a plurality of solutions to the above-described problems. In one example, an electronic control device includes a first chassis, a second chassis fixed to face the first chassis, and a sealant that seals an internal space formed by the first chassis and the second chassis, in which the sealant includes an OH group and a CH₃ group, and a surface treatment film including the OH group and the CH₃ group is formed on at least a part of a surface region of at least one of the first chassis and the second chassis, the surface region coming into contact with the sealant.

### Advantageous Effects of Invention

According to the present invention, an airtight structure can be maintained without largely changing a structure of a sealant filled in a gap between a case and a cover even under a requirement against salt damage that is becoming stricter. Problems, configurations, and effects other than those described above will become clear through the following description of embodiments.

### BRIEF DESCRIPTION OF DRAWINGS

FIG. 1 is a perspective view of an electronic control device according to a first embodiment of the present invention.

FIG. 2 is a cross-sectional view of an essential part in FIG. 1.

FIG. 3 is a schematic view of a cross-sectional chemical structure of a steel plate surface before adhesion in the first embodiment.

FIG. 4 is a schematic view of a cross-sectional chemical structure of the steel plate surface after first adhesion.

FIG. 5 is an example analysis result of the steel plate surface before adhesion in the first embodiment.

FIG. 6 is an example treated region of a surface treatment layer on the steel plate surface in the first embodiment.

FIG. 7 is a schematic view of a cross-sectional chemical structure of a steel plate surface before adhesion in a reference art.

FIG. 8 is an example analysis result of the steel plate surface before adhesion in a reference art.

FIG. 9 is a schematic view of a cross-sectional chemical structure of the steel plate surface after adhesion in the reference art.

FIG. 10 is a cross-sectional view of an essential part of an electronic control device according to a second embodiment of the present invention.

FIG. 11 is a cross-sectional view of an essential part of an electronic control device according to a third embodiment of the present invention.

FIG. 12 is a cross-sectional view of an essential part of an electronic control device according to a fourth embodiment of the present invention.

FIG. 13 is a cross-sectional view of an essential part of an electronic control device according to a fifth embodiment of the present invention.

FIG. 14 is a cross-sectional view of an essential part of an electronic control device according to a sixth embodiment of the present invention.

### DESCRIPTION OF EMBODIMENTS

Hereinafter, an electronic control device according to first to sixth embodiments of the present invention will be described with reference to the drawings. In the drawings used in the present specification, the same or corresponding components are denoted by the same or similar reference sign, and repeated description of these components may be omitted.

### First Embodiment

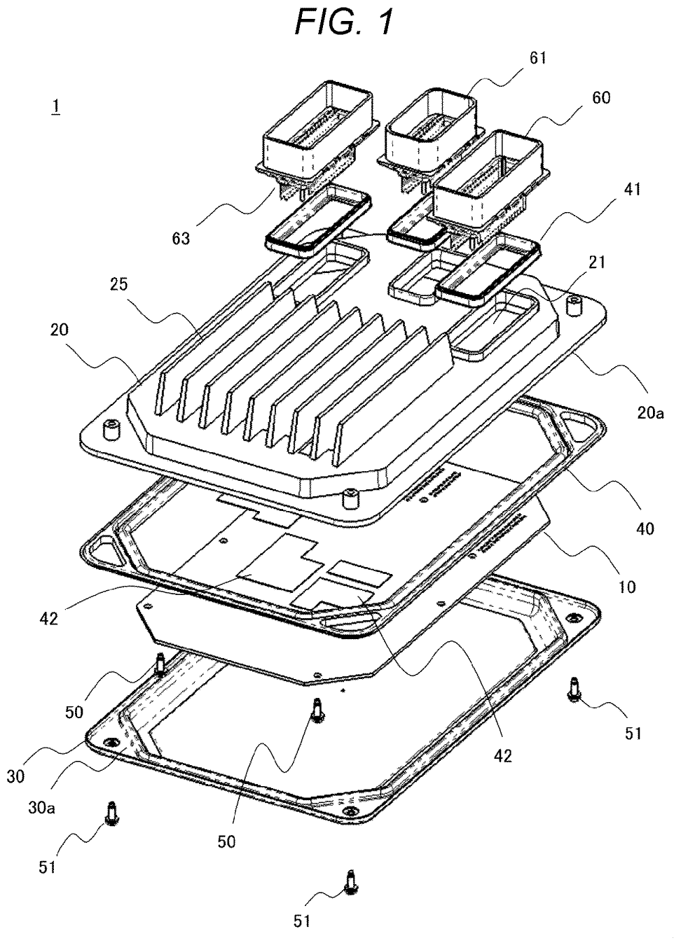

A first embodiment of an electronic control device of the present invention will be described with reference to FIGS. 1 to 9.

First, a general configuration of an electronic control device will be described with reference to the drawings including FIG. 1. FIG. 1 illustrates a perspective view of an electronic control device according to a first embodiment of the present invention. In FIG. 1, for convenience of illustration, electronic components mounted on a board are omitted.

As illustrated in FIG. 1, the electronic control device 1 includes a printed wiring board 10 on which electronic components are mounted, a first chassis 20 (case), a second chassis 30 (cover), a connector 60, a sealant 40, a sealant 41, screws 50, and screws 51.

The first chassis 20 and the second chassis 30 together accommodate the printed wiring board 10 to protects the printed wiring board 10 on which the electronic components are mounted from water, foreign substances, and the like. The first chassis 20 is preferably made of metal, more preferably of aluminum, to dissipate heat generated by the electronic component and to shield noise. In particular, the electronic control device 1 for a direct injection engine is required to have a shielding property.

The first chassis 20 is molded by an aluminum die-casting using a die. For an electronic control device including an electronic component that needs no heat dissipation or shielding, the material of the first chassis 20 may be a resin. In a case of resin, the first chassis 20 is formed by injection molding.

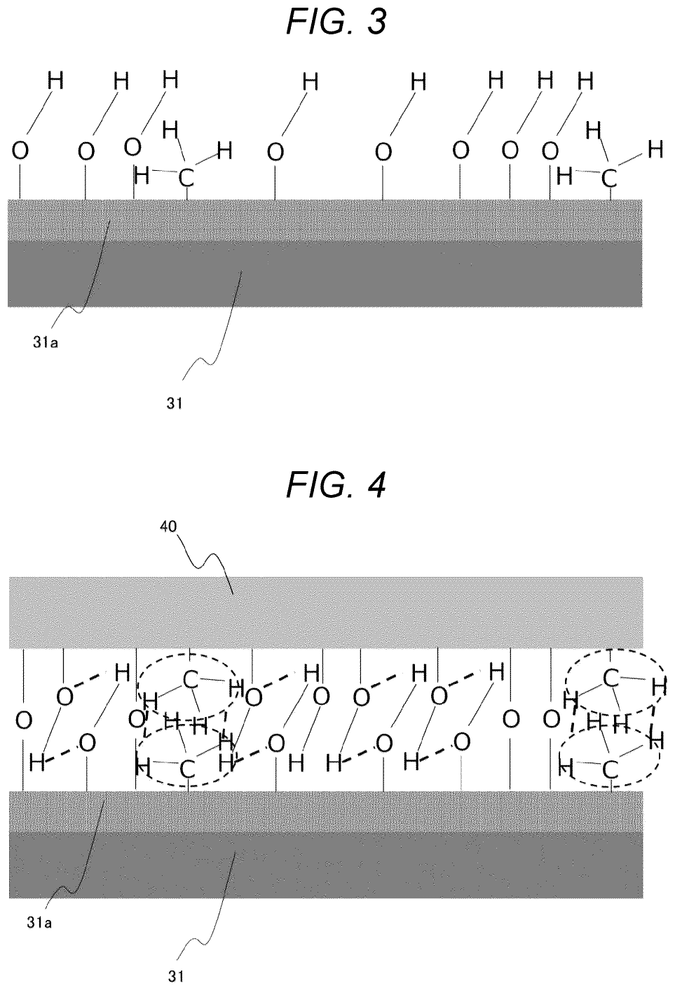

The second chassis 30 is fixed to face the first chassis 20 and seals the internal space 11 (FIG. 3) paired with the first chassis 20.

The external shape of the electronic control device 1 of the present invention is a rectangular shape, preferably about 240 mm×160 mm which is relatively large among electronic control devices mounted in an engine room. Atypical electronic control device has a size of about 160 mm×160 mm, and the electronic control device 1 of the present embodiment preferably has a size 1.5 times or more of the size of a typical electronic control device.

The first chassis 20 is provided with a through opening 21. The opening 21 allows a connector 60 to run therethrough. The inside pressure of the first chassis 20 rises under an environment of a car transported or used with a change in altitude and temperature, and the first chassis 20 deforms such that the displacement in a concave-convex direction (vertical direction in FIG. 1) becomes maximum at the central portion of the first chassis 20. Thus, the through opening 21 is preferably far from the center of the case.

On a side opposite to the opening 21, heat dissipation fins 25 are provided to increase heat capacity. The heat dissipation fins 25 are oriented to be parallel to the long side of the first chassis 20 as illustrated in FIG. 1, but may be parallel to the short side of the first chassis 20. They are desirably parallel to a gate for molding by aluminum die-casting.

When molding by aluminum die-casting, there are two gate location types.

In the first type, the location is selected to be at the short side, opposite to the opening 21, of the rectangular first chassis with the gate parallel to the longitudinal direction of a connector 60 and the heat dissipation fins 25, and an overflow is located on the short side surface opposite to the gate or on the long side surface.

In the second type, the gate location is at a long side of the rectangular first chassis 20, with an overflow located at the opposite long side. Since molding needs to be performed within a solidifying time of aluminum, the second gate location provides, for a large rectangular size, a further improved metal flow and lesser casting defects. Improved metal flow has advantages of less entrained air, no aluminum die-casting defects such as blow holes and weld marks, less amount of aluminum flowing to an overflow, and low forming cost. When a poor metal flow results in molding defects such as blow holes and weld marks, this may cause deterioration in heat conduction and a crack, which may result not only in deformation but also in adverse effect on strength and appearance. Thus, improvement of metal flow is desired.

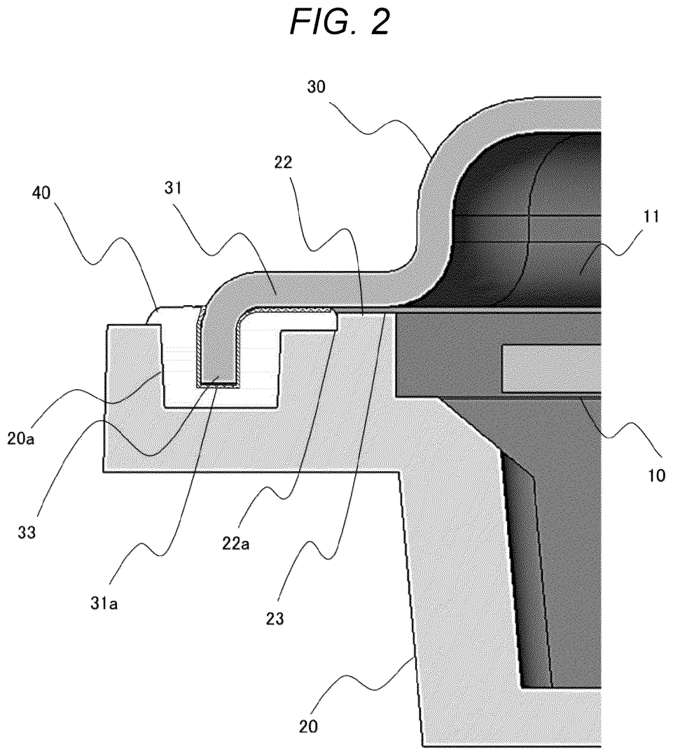

FIG. 2 is a cross-sectional view of an essential part of a case of an electronic control device according to a first embodiment of the present invention. As illustrated in FIG. 2, the first chassis 20 is provided with a rim groove 20a on the entire circumference of the first chassis 20, and has a shaped portion 22 that is provided closer to the internal space side than the sealant 40 and prevents and suppresses the movement of the sealant 40 toward the internal space.

In other words, the first chassis 20 is disposed closer to the internal space 11 than the sealant 40, faces the rim (flange) of the second chassis 30, and has the shaped portion 22 (bank portion) that suppresses the movement (flow) of the sealant 40 toward the internal space 11. This suppresses the sealant 40 sticking out to the internal space. In addition, in a state sandwiched by brackets (fixing members) for fixing to the vehicle, the shaped portion 22 (bank portion) abuts the second chassis to protect the sealant 40.

The shaped portion 22 is set higher than the rim groove 20a. The step-shaped portion 22a may be formed toward the internal space. The step-shaped portion 22a is provided with a first flat portion 23. In other words, the shaped portion 22 (bank portion) has the first flat portion 23 facing the rim (flange) of the second chassis 30.

To prevent movement of the sealant 40, the first flat portion 23 is desirably long but to an extent that does not cause a casting defect in aluminum die-casting. A clearance needs to be secured to avoid the shaped portion 22 making contact with the printed wiring board 10. To suppress the movement of the sealant 40, the surface of the first chassis 20 is roughened by shot blasting or the like. In particular, giving a high surface roughness to the rim groove 20a to which the sealant 40 is applied and the shaped portion 22 and the peripheral thereof suppresses the movement of the sealant 40. Since the sealant 40 is outside the internal space, crevice electrochemical corrosion does not progress.

The first chassis 20 has a plurality of raised portions for fixing the printed wiring board 10. For example, a raised portion with a tapped hole to fasten a screw 50 therein and a raised portion with a surface with high surface accuracy to apply the heat dissipating adhesive 42 thereon are provided. Further, the first chassis 20 is also provided with a raised portion to fix the second chassis 30 via the screws 51.

The second chassis 30 has an edge 33 on the entire circumference of the second chassis 30. The sealant 40 applied between the edge 33 and the rim groove 20a of the first chassis 20 provides protection against foreign substances, such as salt water, required by environmental specifications of the engine room.

In other words, the second chassis 30 faces the first chassis 20 and are fixed by the screws 51. The sealant 40 is provided between the rim of the first chassis 20 and the rim of the second chassis 30 to seal the internal space formed by the first chassis 20 and the second chassis 30. The first chassis 20 has the rim groove 20a adjacent to the shaped portion 22 (bank portion) and filled with the sealant 40. The second chassis 30 has an edge 33 inserted in the rim groove 20a. This improves watertightness.

The material of the second chassis 30 serving as a cover is preferably an iron-based or aluminum-based steel plate, but may be a resin or a die casted aluminum. Metal has less effect of electromagnetic waves. Also, metal receives no effect of electromagnetic waves from others.

The second chassis 30 is preferably a steel plate having a constant thickness and formed by press forming. For a steel plate, it is still preferable that it is plated. Plating is of zinc, aluminum, or magnesium, which has high corrosion resistance in the engine room environment. For a pre-plated steel plate, a cut surface created during forming is not plated, so that the edge 33 is buried in the sealant 40 or the like to be protected against corrosion. The clearance between the edge 33 and the rim groove 20a sufficiently secures a sufficient thickness of the sealant 40 to maintain the adhesive force of the sealant 40. To sandwich the sealant 40 between the second chassis 30 and the first chassis 20, the second chassis 30 has a second flat portion 31 provided on the sealant side and parallel with the first flat portion 23. In other words, the second chassis 30 has the second flat portion 31 facing the first flat portion 23.

The edge 33 is formed by press bending. It is desirable that the rim groove 20a and the edge 33 form a labyrinth structure. The gap between the first flat portion 23 and the second flat portion 31 needs to be as small as to prevent the movement of the sealant 40. In other words, a gap is formed between the shaped portion 22 (bank portion) and the second chassis 30. This surely prevents electrochemical corrosion.

Electronic components and the like are mounted on the printed wiring board 10 using a conductive alloy such as solder. Electronic components can also be mounted on both sides. The electronic components include passive components such as resistors and capacitors and active components such as semiconductors, and are mounted on the printed wiring board by surface mounting or through hole mounting. It is desirable to adopt a long-life electronic component that is durable under the engine room environment of a car.

To increase a mounting density of a package of electronic components, a high-density ball grid array (BGA) or a quad for non-lead package (QFN) is mounted together with a quad flat package (QFP) which has extended lead terminals. The BGA has electrodes of a conductive alloy formed in a hemispherical shape by surface tension to form terminals in a lattice arranged on a bottom surface of the package, and is joined to the printed wiring board 10 by reflow soldering. The QFN has terminals shorter than those of the QFP, and is connected to the printed wiring board 10 with a conductive alloy. This structure tends to easily produce stress at a joint when the printed wiring board 10 deforms by a large amount, so that deformation of the printed wiring board 10 needs to be suppressed to be low.

As illustrated in FIG. 1, the printed wiring board 10 is fixed to the raised portion having a tapped hole of the first chassis 20 together with a plurality of screws 50. In this process, a heat dissipating adhesive 42 is fixed by being sandwiched between the printed wiring board 10 and the raised portion having a high surface accuracy of the first chassis 20, so as to transfer the heat generated by the electronic component to the raised portion through a via of the printed wiring board 10 and dissipate heat from the surface of the first chassis 20 including the fins.

The height location of the printed wiring board 10 is desirably at the center between the first chassis 20 and the second chassis 30. Avoiding the printed wiring board 10 being closer to either side prevents limitation on the height of the electronic component to be mounted, thereby avoiding such a problem that tall electronic components cannot be disposed on both surfaces. In addition, the height location of the printed wiring board 10 at the center between the first chassis 20 and the second chassis 30 enables the electronic control device 1 to be made low in height. The low-height electronic control device 1, when mounted in an engine room, makes it easy to secure a space and receive air flow for cooling.

As described above, the electronic control device 1 of the present embodiment is relatively large in size among electronic control devices disposed in an engine room, so that preferably four to seven screws 50 are used to fix the printed wiring board 10 to the first chassis 20 via the heat dissipating adhesive 42.

The screws 50 are desirably located at four corners of the printed wiring board 10 and at places at a constant interval between the screws 50 considering the arrangement of electronic components. In particular, since strain is produced near the screw 50 in the printed wiring board 10, it is desirable that the screws 50 are not located close to conductive alloy joints of the connector 60, a BGA, and a QFN so that strain is not produced in the joints.

The screws 50 serve as the ground of the case, and the ground (GND) wiring pattern of the printed wiring board 10 is electrically connected to the first chassis 20 via the screws 50. The ground of the case is desirably located at four corners of the printed wiring board 10 considering routing of the wiring pattern of the printed wiring board 10.

The printed wiring board 10 is preferably a glass epoxy board in which an epoxy resin is impregnated into a stack of glass fibers, is a multilayer board in which insulators and patterns are stacked, and is a multilayer board of four to six layers for a requirement of high-density mounting. In addition, a through-hole board in which wiring between layers is made via a through hole or a build-up board made by a build-up process is preferable.

The heat dissipating adhesive 42 conducts heat generated by the electronic component to the raised portion having high surface accuracy of the first chassis 20 through a via of the printed wiring board 10. The thinner the heat dissipating adhesive 42 is, more heat is conducted. Deformation of the first chassis 20 in the normal direction (toward the upper side in FIG. 1) increases the clearance between the first chassis 20 and the printed wiring board 10 and deteriorates heat dissipation. Thus, it is effective to suppress the deformation of the first chassis 20. The electronic component that generates heat and needs heat dissipation is disposed below the heat dissipation fins 25.

The connector 60 includes a housing 61, a terminal 63, and a potting material (omitted for convenience of illustration), and is connected to the printed wiring board 10.

The terminal 63 is press-formed from a copper-based material having a high thermal conductivity. The terminal 63 has a linear shape to be readily guided to a harness side connector or a through hole of the printed wiring board, and has a crimping portion on the tip thereof. The housing 61 is formed of a resin by injection-molding, and the terminal 63 is press-fitted in the housing 61. Alternatively, the housing 61 may be insert-molded with the terminal 63. Since there is a gap between the housing 61 and the terminal 63, the potting material is provided for airtightness.

The size of the connector 60 depends on the number of poles of the terminal 63 and the width of the terminal 63. The terminal 63 has a total of about 60 to 80 poles including terminals for signals and terminals for power which are different in current capacity. The terminals for power are wider. The terminal 63 and the through-hole of the printed wiring board 10 are connected using a conductive alloy such as solder (not illustrated). Alternatively, a press-fit terminal (not illustrated) that makes connection mechanically and electrically may be used.

In the first embodiment, there are three connectors 60, but the number is not limited to three and may be three or more. In such a case, accordingly, the number of openings 21 of the first chassis will be three or more. With the center connector 60 disposed on the outermost side, the area for mounting the electronic components can be increased. In addition, the wiring pattern of the printed wiring board 10 will not be highly dense, and overlapping of wiring patterns can be avoided.

The connector 60 of the first embodiment is assembled such that the connector 60 is connected via the sealant 41 on the outer side of the opening 21 of the first chassis 20, but the connector 60 may be first connected to the printed wiring board 10 and then connected via the sealant 41 disposed on the inner surface of the opening 21 of the first chassis 20. Connecting the connector 60 from the outer side of the opening 21 of the first chassis 20 is advantageous in that the sealing structure of the connector 60 can be downsized.

The detail of connecting the connector 60 to the first chassis 20 is that the sealant 41 disposed around the bottom of the housing of the connector 60 is cured to create sealing. When the peripheral portion of the connector 60 of the first chassis 20 deforms toward the normal direction by expansion of the inside of the first chassis 20 by the effect of heat or pressure, the sealant 41 functions as a cushioning material, but the connector 60 also deforms at the same time since the clearance is small. The deformation of the connector 60 affects also the terminal 63, and propagates to the printed wiring board 10 via the conductive adhesive at the same time.

The sealant 41 is provided for watertightness, and for protection against foreign substances, such as salt water, required by environmental specifications for an engine room, so that a silicone adhesive having heat resistance, water resistance, chemical resistance, and flexibility is preferable.

The sealant 40 is provided for watertightness and is a member for sealing the internal space formed by the first chassis 20 and the second chassis 30. A silicone adhesive is preferable for the same reason for that of the sealant 41. In particular, when the pressure inside the first chassis 20 changes by temperature change, the pressure inside the first chassis 20 causes the first chassis 20 to curve such that the center of the first chassis 20 swell in the normal direction (upper direction in FIG. 1), and the deformation of the long side of the first chassis 20 becomes maximum at the center thereof. Therefore, the sealant 40 can have an adhesive force that can withstand the deformation.

At four corners of the second chassis 30, there are provided holes through which the screws 51 for fixing the first chassis 20 and the second chassis 30 are inserted through. The second chassis 30 and the first chassis 20 are fixed together with the sealant 40 by the screws 51. It is desirable to locate the screws 51 at the four corners so that the route of applying the sealant 40 will not be intricate. Since the electronic control device 1 of the present embodiment is preferably 1.5 times larger in size than a conventional typical electronic control device, a thin material is selected for the second chassis 30, but the second chassis 30 has ribs, dimples, steps, and the like to secure strength.

As illustrated in FIGS. 2 and 3, in the present embodiment, the sealant 40 has an OH group and a CH₃ group, and at least one of the first chassis 20 and the second chassis 30 (in the present embodiment, only the second chassis 30) has a surface treatment film 31a including an OH group and a CH₃ group formed on at least a part (in the present embodiment, a part of the second flat portion 31) of a surface region, in contact with the sealant 40, of at least one of the first chassis 20 and the second chassis 30. Furthermore, the sealant 40 and the surface treatment film 31a have a structure in which the existing OH group and the CH₃ group are exposed on the surface. In FIG. 2, the surface treatment film 31a is formed on a surface buried in the sealant 40. FIG. 3 illustrates an example chemical cross-sectional structure of the surface treatment film 31a before adhesion to the sealant 40.

This OH group, during applying and curing of the sealant 40, reacts with the OH group of the sealant 40, and adhesion is established by a hydrogen bond or a covalent bond. In addition, adhesion is established by intermolecular force (van der Waals force) between the CH₃ group and the CH₃ group of the sealant. Since there are more OH groups than a conventional structure, the hydrogen bond and the covalent bond create strong force. Moreover, additional water-resistant intermolecular force maintains high adhesion also after a salt damage test (FIG. 4) as compared with the conventional structure. In FIG. 4, a dotted circle indicates an intermolecular force, a dotted straight line indicates a hydrogen bond, and a solid straight line indicates a covalent bond. It should be noted that the conceptual diagram is not limited to FIG. 4.

The material of the component of the surface treatment film 31a is not limited as long as it has an OH group and a CH₃ group, but it is more preferable that the component is a Si-based, in particular, a glass-based material in terms of performance and easiness of forming of the surface treatment film 31a.

The thickness of the surface treatment film 31a is not limited as long as the surface treatment film 31a has an OH group and a CH₃ group, but is more preferably 50 nm to 140 nm in terms of process cost.

In a case of a glass-based material, it is preferable that the surface treatment film 31a is formed by plasma glass coating that can establish high adhesion to the second flat portion 31. The plasma glass coating is preferably formed by attaching to a plasma processing apparatus (Plasmatreat: PTU1212) a nozzle (Plasmatreat: PFW10), a plasma control unit (Plasmatreat: PCU), and a plasma generator (Plasmatreat: FG5002S) and processing using hexamethyldisiloxane or hexamethyldisilazane as a precursor.

Note that the precursor is not limited to the above, and any precursor in which a Si group has a functional group of a carbon chain such as a CH₃ group can be used.

The surface treatment film 31a may be formed by a method other than forming plasma glass coating as long as high adhesion to the second flat portion 31 can be established. It is further preferable that the surface treatment film 31a is directly formed on the second flat portion 31 with an adhesive strength of 1.0 MPa or more. The number 1.0 MPa indicates the cohesive failure strength of a typical silicone-based sealant. In other words, it indicates that the adhesion strength between the second flat portion 31 and the surface treatment film 31a is equal to or higher than the cohesive failure strength of the silicone-based sealant, and this number is not a limitation as long as this relationship is satisfied.

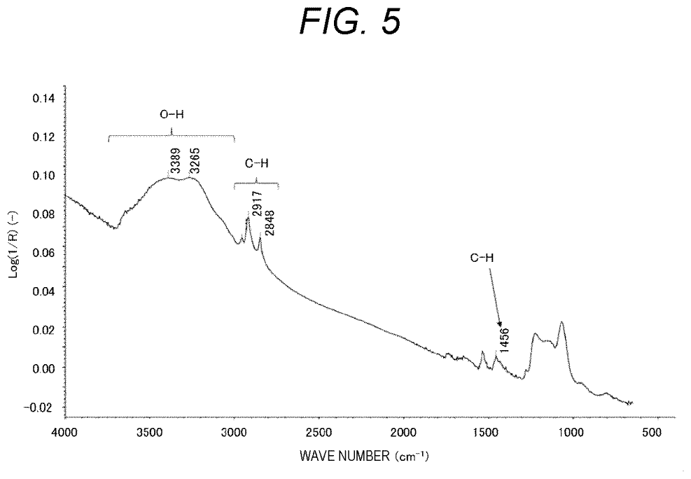

The functional group can be detected by, for example, Fourier transform infrared spectroscopy (FTIR) measurement. An example measurement is shown in FIG. 5. FIG. 5 indicates that an OH group is detected around 3300 cm⁻¹, and a CH group is detected around 2900 cm-1 and 1400 cm⁻¹. Measured wave numbers slightly fluctuate at each time, so that the wave numbers are not limited to the wave numbers indicated in FIG. 5. This example measurement includes all the wavenumbers determined to be OH groups or CH groups according to comparison with a typical FTIR wavenumber database.

The FTIR measurement is performed, for example, using a Fourier transform infrared spectroscopic analyzer (Thermo Fisher Scientific: Nicolet 6700 Micro Infrared Analyzer Nicolet Continuum) by a microscopic reflection method under the conditions of a resolution of 4 cm⁻¹, using a MCT detector, and 64 integration times, in which method the peak intensity of each functional group can be recognized from the correction height from the background.

Note that the measuring device and the method are not limited to the above, and any device and condition that can correctly detect the functional group on the surface can be used.

Quantitatively more preferable range of the functional groups present in the surface treatment film 31a are as described later.

For example, from a relative ratio and a value with which more desirable adhesive strength was obtained among the results obtained by forming and evaluating the surface treatment films with actually different relative ratios, the surface treatment film 31a having a Si-based component, in particular, a glass-based component can be formed to have 0.1 or more C—H bonds of CH₃ group in a relative ratio, CH/SiO, with respect to SiO group, or 0.5 or more OH groups in a relative ratio, OH/SiO, with respect to SiO group.

For the surface treatment film 31a of which component is not a Si-based (no SiO), it is more preferable that the surface treatment film 31a has an intensity ratio CH/OH of 0.1 or more, or has absorbance peak heights with background correction of 0.001 or more for CH group and 0.01 or more for OH group, the absorbance being measured by FTIR and plotted with the vertical Log axis.

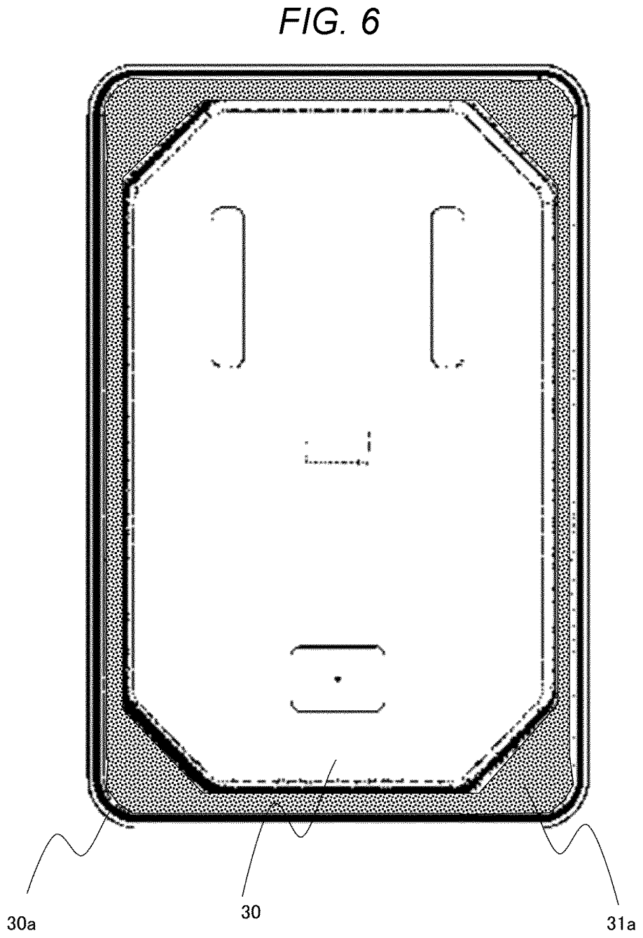

In case when the sealant 40 absorbs water, the presence of the surface treatment film 31a having the above-described structure suppresses the contact of the second flat portion 31 with water, and this leads to prevention of corrosion and the like of the second flat portion 31. FIG. 6 illustrates an example of a region on the second chassis 30 where the surface treatment film 31a is formed. It is preferable that the surface treatment film 31a is formed on the chassis edge 30a that contacts the sealant 40, but the treated region may be the entire second chassis 30, and is not limited to the above.

Next, effects of the present embodiment will be described.

The electronic control device 1 according to the first embodiment of the present invention described above includes a first chassis 20, a second chassis 30 fixed to face the first chassis 20, and a sealant 40 that seals an internal space formed by the first chassis 20 and the second chassis 30, in which the sealant 40 includes an OH group and a CH₃ group, and a surface treatment film 31a including the OH group and the CH₃ group is formed on at least a part of a surface region of at least one of the first chassis 20 and the second chassis 30, the surface region coming into contact with the sealant 40.

In the present invention, the OH group that adheres to the OH group of the sealant by a hydrogen bond or a covalent bond is enhanced as compared with a surface state of a normal metal, and as another feature, the CH₃ group that adheres to the CH₃ group of the sealant by intermolecular force (van der Waals force) is added.

As a result, a certain amount of OH group can be provided regardless of a metal surface state. This enables adhesion by increased numbers of hydrogen bond and covalent bond, and in addition, adhesion by intermolecular force, of which water resistance is not low. Thus, high adhesion can be maintained even after a salt damage test as compared with the conventional structure.

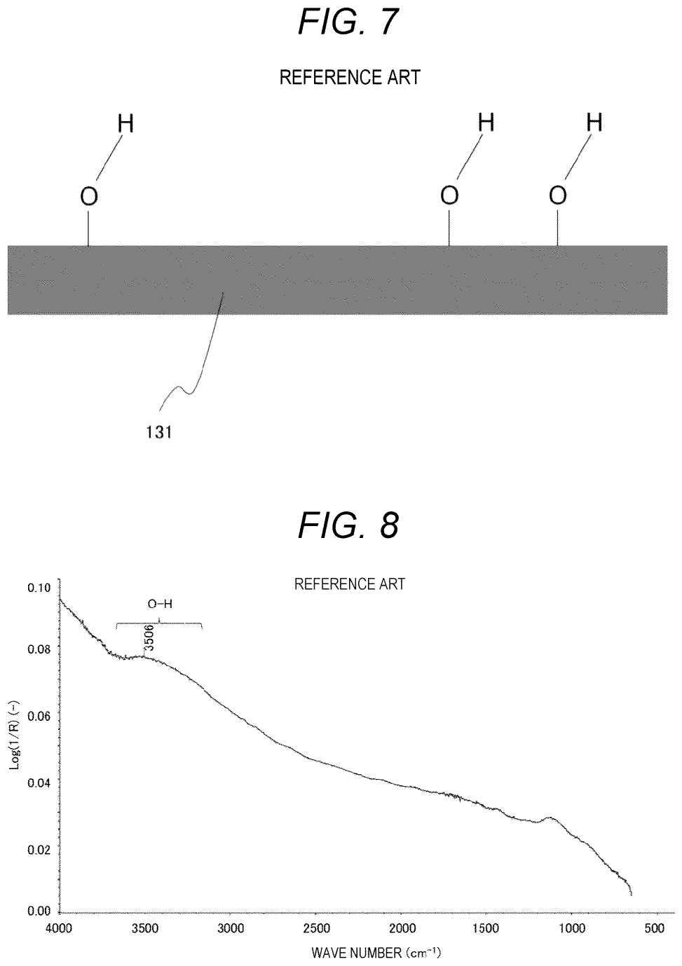

In the environmental resistance test against salt water or the like so far, it is considered that the requirement of adhesion can be satisfied with the structure in FIG. 7 or the like. Under such a requirement that has become stricter as in recent years, the structure like that of the electronic control device 1 of the present embodiment can maintain an airtight structure without largely changing the structure of the electronic control device in which the sealant is filled between the case and the cover. The present embodiment provides a sealing structure of an electronic control device that is excellent in environmental resistance against salt water or the like and can maintain high adhesion after a durability test as compared with a conventional electronic control device. Thus, an electronic control device with high robustness, high adhesion, and high reliability can be newly provided.

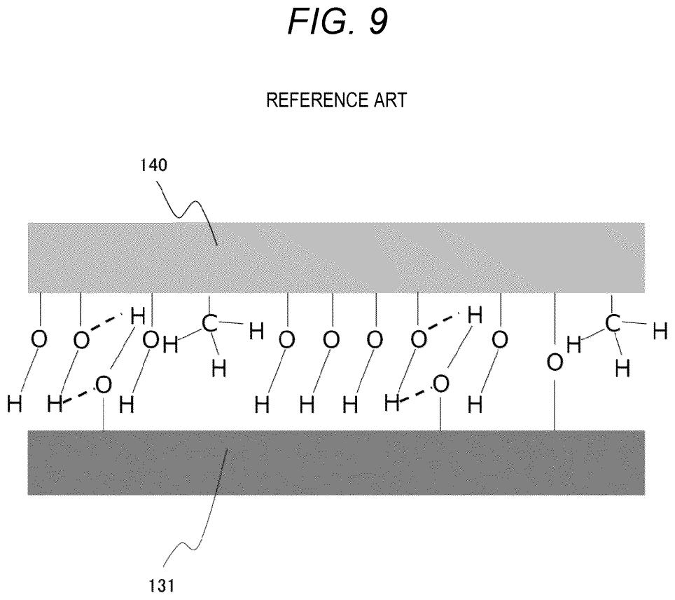

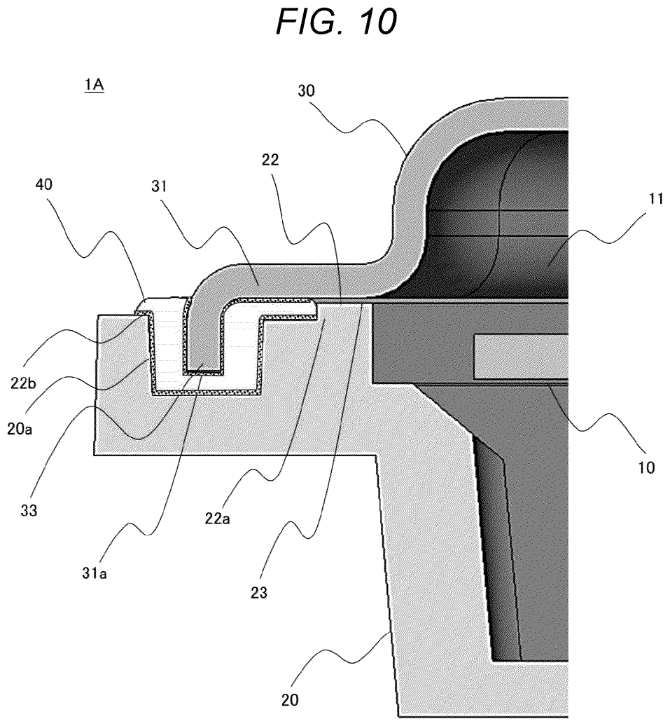

FIG. 7 is a schematic view of a chemical structure of a cross section of a chassis 131 of a conventional structure, FIG. 8 illustrates an example analysis thereof, and FIG. 9 is a schematic view of a chemical structure after adhesion to a sealant 140. With only the chassis 131, the functional group that adheres to the sealant 140 is limited and the amount of the functional group is unstable depending on a chassis.

### Second Embodiment

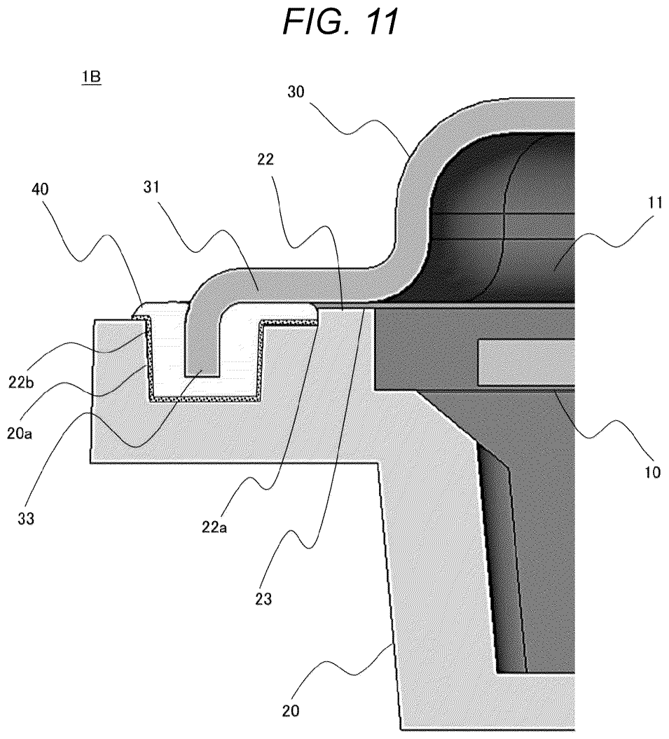

An electronic control device according to a second embodiment of the present invention will be described with reference to FIG. 10. FIG. 10 is a cross-sectional view of an essential part of an electronic control device according to a second embodiment of the present invention.

In the electronic control device 1A of the present embodiment illustrated in FIG. 10, a surface treatment film 22b is formed on a first chassis 20 side in addition to a surface treatment film 31a on a second flat portion 31 side. A highly adhesive structure that can be realized in the first embodiment can be given to both sides with which a sealant 40 contacts.

Other configurations and operations are substantially the same as those of the electronic control device of the first embodiment described above, and details thereof will be omitted.

Also in the electronic control device according to the second embodiment of the present invention, effects almost the same as those of the electronic control device according to the first embodiment described above can be obtained, and a sealing structure of an electronic control device which is excellent in environmental resistance against salt water or the like and can maintain high adhesion even after a durability test as compared with a conventional electronic control device can be provided.

### Third Embodiment

An electronic control device according to a third embodiment of the present invention will be described with reference to FIG. 11. FIG. 11 is a cross-sectional view of an essential part of an electronic control device according to a third embodiment of the present invention.

In an electronic control device 1B of the present embodiment illustrated in FIG. 11, a surface treatment film 22b is formed only on a first chassis 20 side. Also in this case, high adhesion can be established by the same mechanism as that of the first embodiment.

Other configurations and operations are substantially the same as those of the electronic control device of the first embodiment described above, and details thereof will be omitted.

Also in the electronic control device according to the third embodiment of the present invention, effects almost the same as those of the electronic control device according to the first embodiment described above can be obtained, and a sealing structure of an electronic control device which is excellent in environmental resistance against salt water or the like and can maintain high adhesion even after a durability test as compared with a conventional electronic control device can be provided.

### Fourth Embodiment

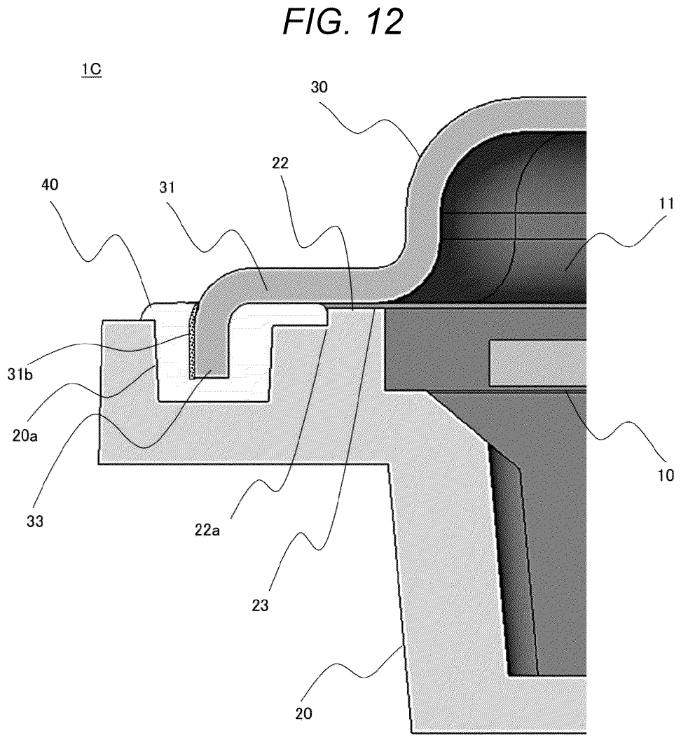

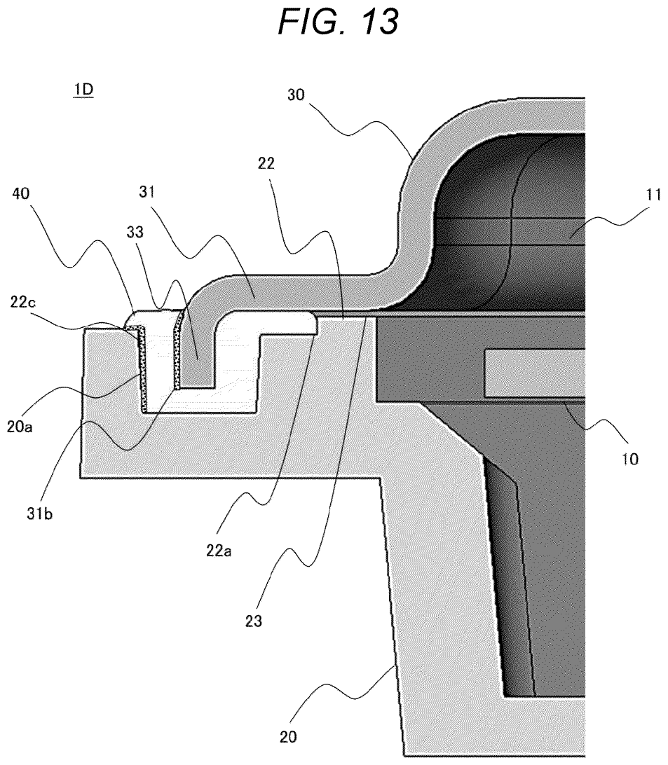

An electronic control device according to a fourth embodiment of the present invention will be described with reference to FIG. 12. FIG. 12 is a cross-sectional view of an essential part of an electronic control device according to a fourth embodiment of the present invention.

In an electronic control device 1C of the present embodiment illustrated in FIG. 12, a surface treatment film 31b is formed on a side of a second flat portion 31 that comes into contact with water during a salt damage test or the like. In other words, the surface treatment film 31b is formed at a portion facing the rim groove 20a. Also in this case, high adhesion can be established by the same mechanism as that of the first embodiment.

Other configurations and operations are substantially the same as those of the electronic control device of the first embodiment described above, and details thereof will be omitted.

Also in the electronic control device according to the fourth embodiment of the present invention, effects almost the same as those of the electronic control device according to the first embodiment described above can be obtained, and a sealing structure of an electronic control device which is excellent in environmental resistance against salt water or the like and can maintain high adhesion even after a durability test as compared with a conventional electronic control device can be provided.

### Fifth Embodiment

An electronic control device according to a fifth embodiment of the present invention will be described with reference to FIG. 13. FIG. 13 is a cross-sectional view of an essential part of an electronic control device according to a fifth embodiment of the present invention.

In the electronic control device 1D of the present embodiment illustrated in FIG. 13, in addition to a surface treatment film 31b formed only on a side, of the second flat portion 31, that comes into contact with water during a salt damage test or the like, a surface treatment film 22c is formed only on a side, of the first chassis 20, that comes into contact with water during a salt damage test or the like.

In other words, the surface treatment films 31b and 22c are formed only on facing portions of the edge 33 and the rim groove 20a. Also in this case, high adhesion can be established by the same mechanism as that of the first embodiment.

Other configurations and operations are substantially the same as those of the electronic control device of the first embodiment described above, and details thereof will be omitted.

Also in the electronic control device according to the fifth embodiment of the present invention, effects almost the same as those of the electronic control device according to the first embodiment described above can be obtained, and a sealing structure of an electronic control device which is excellent in environmental resistance against salt water or the like and can maintain high adhesion even after a durability test as compared with a conventional electronic control device can be provided.

### Sixth Embodiment

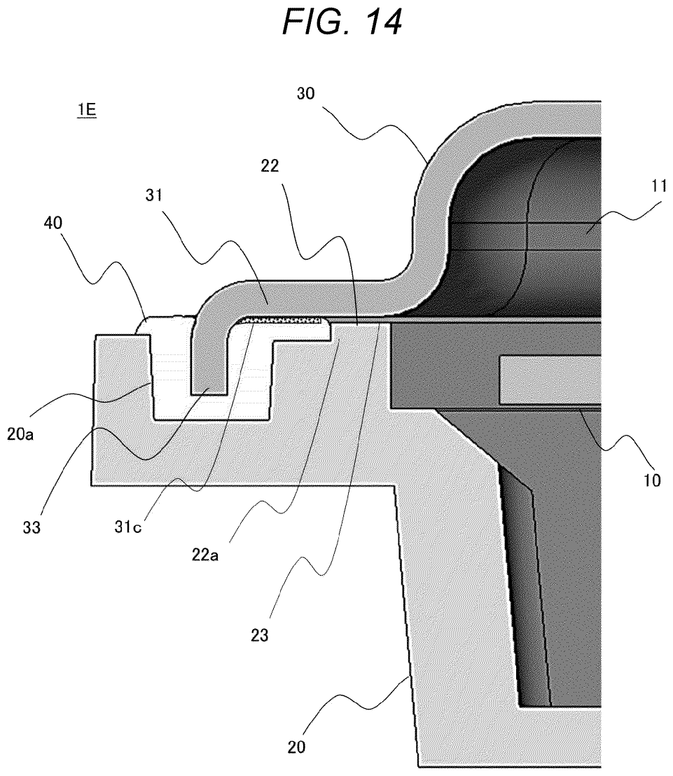

An electronic control device according to a sixth embodiment of the present invention will be described with reference to FIG. 14. FIG. 14 is a cross-sectional view of an essential part of an electronic control device according to a fifth embodiment of the present invention.

In an electronic control device 1E of the present embodiment illustrated in FIG. 14, a surface treatment film 31c is formed on a side, of the second flat portion 31, facing and closer to the rim groove 20a. Also in this case, high adhesion can be established by the same mechanism as that of the first embodiment.

Other configurations and operations are substantially the same as those of the electronic control device of the first embodiment described above, and details thereof will be omitted.

Also in the electronic control device according to the sixth embodiment of the present invention, effects almost the same as those of the electronic control device according to the first embodiment described above can be obtained, and a sealing structure of an electronic control device which is excellent in environmental resistance against salt water or the like and can maintain high adhesion even after a durability test as compared with a conventional electronic control device can be provided.

### <Others>

Note that the present invention is not limited to the above-described embodiments, and includes various exemplary modifications. For example, the above-described embodiments have been described in detail for easy understanding of the present invention, and are not necessarily limited to those having all the described configurations. Further, a part of a configuration of one embodiment can be replaced with a configuration of another embodiment, and a configuration of another embodiment can be added to a configuration of one embodiment. In addition, for a part of a configuration of each embodiment, addition or deletion of other configuration can be made, or the part can be replaced with other configuration.

The embodiment of the present invention may have the following aspects.

(1) An electronic control device including a first chassis, a second chassis fixed to face the first chassis, and a sealant that seals an internal space formed by the first chassis and the second chassis, wherein the sealant includes an OH group and a CH₃ group, and a surface treatment film including the OH group and the CH₃ group is formed on at least a part of a surface region of at least one of the first chassis and the second chassis, the surface region coming into contact with the sealant.

(2) The electronic control device according to (1), wherein a main component of the surface treatment film is of Si-based.

(3) The electronic control device according to (2), wherein the Si-based is a glass-based.

(4) The electronic control device according to (2), wherein the surface treatment film has a C—H bond of the CH₃ group of 0.1 or more in a relative ratio, CH/SiO, with respect to a Si—O bond.

(5) The electronic control device according to (2), wherein the surface treatment film has the OH group of 0.5 or more in a relative ratio, OH/SiO, with respect to a SiO group.

(6) The electronic control device according to claim 1), wherein the surface treatment film has either of an intensity ratio CH/OH of 0.1 or more, or absorbance peak heights with background correction of 0.001 or more for a CH group and 0.01 or more for the OH group, the absorbance being measured by FTIR and plotted with a vertical Log axis.

(7) The electronic control device according to claim 1), wherein the surface treatment film has a thickness of 50 nm or more.

(8) The electronic control device according to claim 7), wherein the surface treatment film is directly formed on surfaces of the first chassis and the second chassis with an adhesive strength of 1.0 MPa or more.

### REFERENCE SIGNS LIST

1, 1A, 1B, 1C, 1D, 1E electronic control device
10 printed wiring board
11 internal space
20 first chassis
20a rim groove
21 opening
22 shaped portion
22a step-shaped portion
22b, 22c, 31a, 31b, 31c surface treatment film
23 first flat portion
25 heat dissipation fin
30 second chassis
30a chassis edge
31 second flat portion
33 edge
40, 41 sealant
42 heat dissipating adhesive
50, 51 screw
60 connector
61 housing
63 terminal
131 chassis
140 sealant

1. An electronic control device comprising:
a first chassis;
a second chassis fixed to face the first chassis; and
a sealant that seals an internal space formed by the first chassis and the second chassis,
wherein the sealant includes an OH group and a CH₃ group, and
a surface treatment film including the OH group and the CH₃ group is formed on at least a part of a surface region of at least one of the first chassis and the second chassis, the surface region coming into contact with the sealant.

2. The electronic control device according to claim 1, wherein a main component of the surface treatment film is of Si-based.

3. The electronic control device according to claim 2, wherein the Si-based is a glass-based.

4. The electronic control device according to claim 2, wherein the surface treatment film has a C—H bond of the CH₃ group of 0.1 or more in a relative ratio, CH/SiO, with respect to a Si—O bond.

5. The electronic control device according to claim 2, wherein the surface treatment film has the OH group of 0.5 or more in a relative ratio, OH/SiO, with respect to a SiO group.

6. The electronic control device according to claim 1, wherein
the surface treatment film has either of
an intensity ratio CH/OH of 0.1 or more, or
absorbance peak heights with background correction of 0.001 or more for a CH group and 0.01 or more for the OH group, the absorbance being measured by FTIR and plotted with a vertical Log axis.

7. The electronic control device according to claim 1, wherein the surface treatment film has a thickness of 50 nm or more.

8. The electronic control device according to claim 7, wherein the surface treatment film is directly formed on surfaces of the first chassis and the second chassis with an adhesive strength of 1.0 MPa or more.
